(19) United States
(12) Patent Application Publication
(10) Pub. No.: US 2026/0314046 A1
(43) Pub. Date: Oct. 8, 2026

(54) TRANSISTOR ISOLATION STRUCTURES

(71) Applicant: Taiwan Semiconductor Manufacturing Company, Ltd., Hsinchu (TW)

(72) Inventors: Wan-Yi KAO, Baoshan Township (TW); Te-En CHENG, Taoyuan City (TW); Chunyao WANG, Zhubei City (TW); Tze-Liang LEE, Hsinchu (TW)

(73) Assignee: Taiwan Semiconductor Manufacturing Company, Ltd., Hsinchu (TW)

(21) Appl. No.: 19/170,711

(22) Filed: Apr. 4, 2025

(51) Int. Cl. H10D 84/83; H01L 21/02; H01L 21/3105; H10D 30/00; H10D 30/01; H10D 30/43; H10D 62/10; H10D 64/01; H10D 64/66; H10D 84/01

(52) U.S. Cl. CPC H10D 84/832; H10D 30/0191; H10D 30/502; H10D 62/102; H10D 62/121; H10D 64/021; H10D 64/679; H10D 84/0147; H10P 14/6687; H10P 14/683; H10P 95/00; H10D 30/014; H10D 30/43

(57) ABSTRACT

The present disclosure is directed to a method for fabricating spacer structures between source/drain (S/D) epitaxial structures and metal gate structures in nanostructure transistors. The method includes forming a fin structure with alternating first and second nanostructured layers on a substrate. The method also includes etching edge portions of the first nanostructured layers in the fin structure to form cavities and depositing a polymer spacer layer within the cavities to form inner spacers. The method further includes forming S/D epitaxial structures on the substrate to abut the fin structure and the inner spacers so that an air gap is formed between sidewall portions of the S/D epitaxial structures and the inner spacers.

### BACKGROUND

Gate-all-around (GAA) field effect transistors (GAA FETs), such as nano-sheet or nano-wire GAA FETs, have improved gate control over their channel regions compared to other types of FETs whose gate structure covers sidewall portions and top surfaces of semiconductor fin structures. Due to their gate-all-around geometry, GAA nano-sheet or nano-wire FETs achieve larger effective channel widths and higher drive currents.

### BRIEF DESCRIPTION OF THE DRAWINGS

Aspects of the present disclosure are best understood from the following detailed description when read with the accompanying figures.

FIG. 1A illustrates an isometric view of a semiconductor device, in accordance with some embodiments.

FIG. 1B is a cross-sectional view of a semiconductor device, in accordance with some embodiments.

FIGS. 2A and 2B are flowcharts of a method for the formation of inner spacers between gate structures and source/drain epitaxial structures of a semiconductor device, in accordance with some embodiments.

FIGS. 3 and 4 are isometric views of intermediate structures during the fabrication of inner spacers between gate structures and source/drain epitaxial structures of a semiconductor device, in accordance with some embodiments.

FIGS. 5, 6, 7A, 7B, 8A, and 8B are cross-sectional views of intermediate structures during the fabrication of inner spacers between gate structures and source/drain epitaxial structures of a semiconductor device, in accordance with some embodiments.

FIGS. 9A, 9B, and 9C are magnified cross-sectional views of intermediate structures during the fabrication of inner spacers between gate structures and source/drain epitaxial structures of a semiconductor device, in accordance with some embodiments.

FIGS. 10A, 10B, and 10C illustrate chemical reactions involved in the formation of a polymer layer for inner spacers between gate structures and source/drain epitaxial structures of nanostructure transistors, in accordance with some embodiments

FIGS. 11 through 15 are cross-sectional views of intermediate structures during the fabrication of inner spacers between gate structures and source/drain epitaxial structures of the semiconductor device, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over a second feature in the description that follows may include embodiments in which the first and second features are formed in direct contact, and may also include embodiments in which additional features may be formed that are between the first and second features, such that the first and second features are not in direct contact.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In some embodiments, the terms “about” and “substantially” can indicate a value of a given quantity that varies within 5 % of the value (e.g., ±1%, ±2%, ±3%, ±%, ±5% of the value). These values are merely examples and are not intended to be limiting. It is to be understood that the terms “about” and “substantially” can refer to a percentage of the values as interpreted by those skilled in relevant art(s) in light of the teachings herein.

By way of example and not limitation, nanostructure transistors, like gate-all-around field effect transistors (referred to as “GAA FETs”) with nanostructured channel layers, can be formed as follows. A fin-like structure with alternating silicon nanostructured channel layers and silicon-germanium (SiGe) nanostructured layers is formed on a substrate (e.g., on a semiconductor substrate). A sacrificial gate structure is then formed on a middle portion of the fin-like structure to cover top and sidewall surfaces of the fin-like structure so that edge portions of the fin-like structure are not covered by the sacrificial gate structure. The portions of the fin-like structure not covered by the sacrificial gate structure are removed. Subsequently, edge portions of the SiGe nanostructured layers are recessed with respect to edge portions of the Si nanostructured layers (also referred to herein as “nanostructured channel layers”) to form spacer cavities, and inner spacer layers are deposited to fill the spacer cavities. The inner spacer layer outside the spacer cavities is removed, for example, by an anisotropic dry etching process. Un-etched portions of the inner spacer layers within the spacer cavity form inner spacers. Source/drain (S/D) epitaxial structures are then formed to abut edge portions of the fin-like structures so that the S/D epitaxial structures are in contact with the Si nanostructured channel layers and isolated from the SiGe nanostructured layers by the inner spacers. At a later operation, the sacrificial gate structure is removed to expose the top and sidewall surfaces of the fin structure. The SiGe nanostructured layers are selectively removed from the fin-like structure. During the selective removal process, the Si nanostructured channel layers and the inner spacers are not removed. Subsequently, a metal gate structure is formed to surround the Si nanostructured channel layers. Similar to the SiGe nanostructured layers prior to their selective removal, the metal gate structure is isolated from the S/D epitaxial structures through the inner spacers.

In GAA FET structures, inner spacers provide isolation between the gate structure and the source/drain (S/D) epitaxial structures. Inner spacer layer deposition is a horizontal gap-fill process, which can be accomplished using chemical vapor deposition (CVD) or atomic layer deposition (ALD). Inner spacer layers are deposited on inner sidewalls of spacer cavities using CVD or ALD. The inner spacer layers are deposited within the spacer cavities on (a) a sidewall of the SiGe nanostructured layer and (b) top and bottom horizontal surfaces of Si nanostructured channel layers. As the deposition process progresses, these inner spacer layers on the sidewalls coalesce to form the inner spacer within the spacer cavities. However, as these inner spacer layers coalesce, they can form a seam or an air gap within the inner spacer layer. During a subsequent etching process to remove inner spacer layers from vertical sidewalls of the Si nanostructured channel layers, the seam or air gap within the inner spacer layer can open. An open air gap can cause over etching of the inner spacer layer. The over-etched inner spacer layer does not provide adequate isolation between the S/D epitaxial structures and nanostructured channel layers to prevent leakage current.

Despite providing isolation, inner spacers can contribute to parasitic capacitance between the S/D epitaxial structures and the gate structures. An inner spacer with a low dielectric constant can lower this parasitic capacitance. Inner spacers formed of materials, such as silicon nitride (SiN), silicon oxycarbonitride (SiOCN), and silicon oxycarbonitride (SiOC), deposited by CVD or ALD can have a dielectric constant of greater than 5. Additionally, materials, such as SiN, SiOCN, and SiOC, can form a thick inner spacer layer on vertical sidewalls of Si nanostructured channel layers. Since the inner spacer layer formed on vertical sidewalls of Si nanostructured channel layers have to be subsequently etched, a thick inner spacer layer can require a long etching time.

The present disclosure provides an inner spacer that does not include a seam or an air gap and a method of forming the same. The inner spacer is formed of a flowable polymer (also referred to herein as “polymer layer”). The polymer layer can have a dielectric constant, for example, less than about 4.0. This helps reduce the parasitic capacitance between the S/D epitaxial structure and the gate structure. The dielectric constant of the polymer layer can be tuned by varying the ratio of oxygen to silicon (O:Si) in the polymer layer. An increase in O:Si ratio and/or a decrease in a nitrogen content in the polymer layer can reduce the dielectric constant of the polymer layer. On the other hand, an increase in carbon content can reduce leakage current between the S/D epitaxial structures and the gate structures. An increased carbon content can also increase a density of the polymer layer. The polymer layer can have a density, for example, between about 2.0 g/cm³ and about 2.6 g/cm³.

The method of forming the polymer layer forms a thicker polymer layer within the spacer cavities than on the vertical sidewalls of the nanostructured channel layers outside the spacer cavities, according to the some embodiments. This reduces the etching time for removing the polymer layer outside the spacer cavities (e.g., polymer layer on the vertical sidewalls of the nanostructured channel layers). The disclosed method of forming polymer-based inner spacers prevents formation of seams or air gaps within the inner spacer layer.

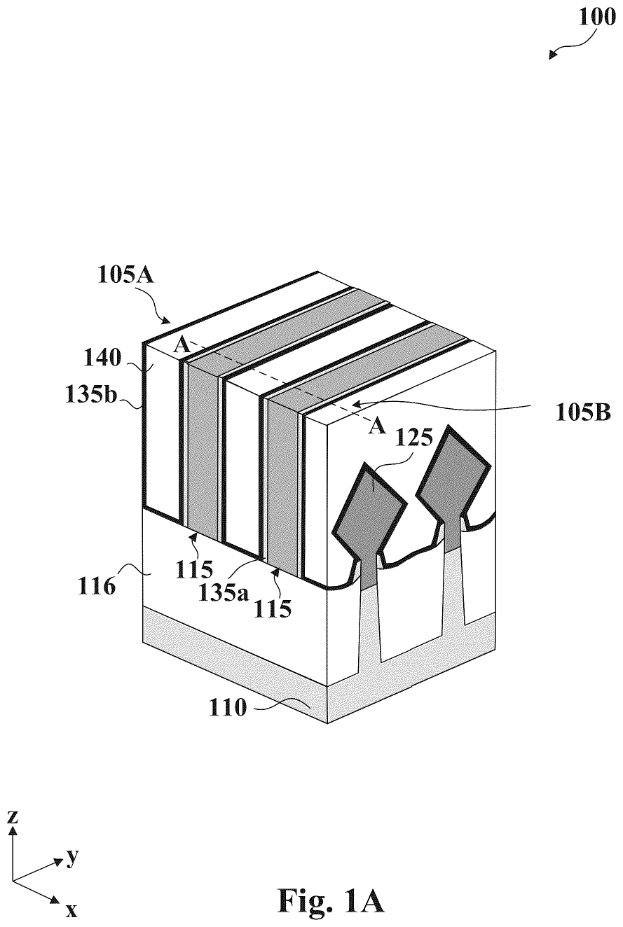

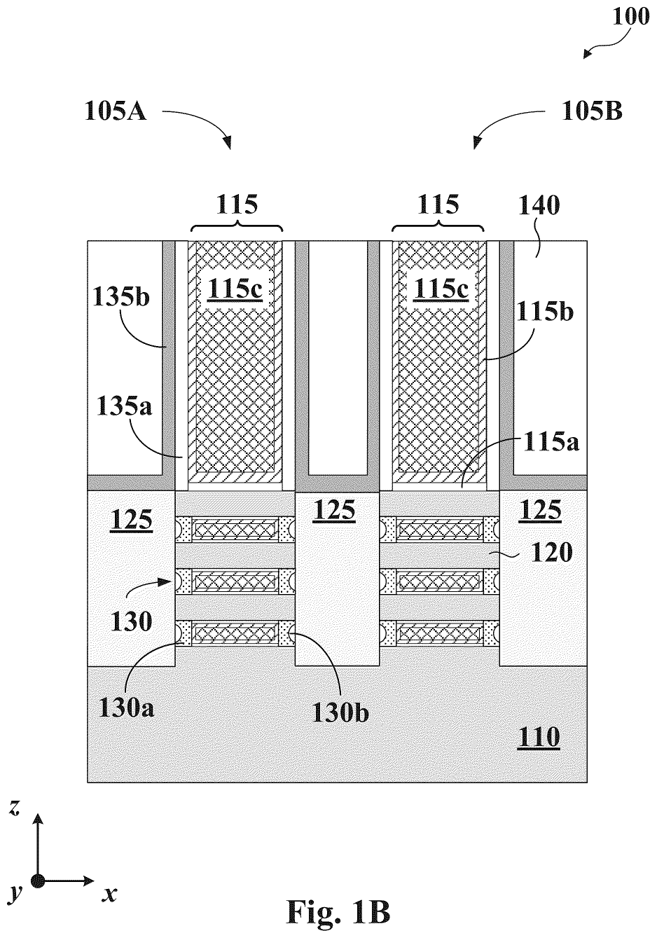

A semiconductor device 100 with GAA FETs 105A and 105B is described with reference to FIGS. 1A and 1B, according to some embodiments. Though two GAA FETs are discussed with reference to FIGS. 1A and 1B, semiconductor device 100 can have any number of GAA FETs. GAA FETs 105A and 105B can be n-type, p-type, or a combination thereof. FIG. 1A illustrates an isometric view of semiconductor device 100, according to some embodiments. Semiconductor device 100 can have a different cross-sectional view along line A-A of FIG. 1A, according to some embodiments. Line A-A can extend along the x-axis.

According to some embodiments, FIG. 1B illustrates a cross sectional view of GAA FETs 105A and 105B along line A-A of FIG. 1A. FIG. 1B illustrates a cross-sectional view of GAA FETs 105A and 105B with additional elements that are not shown in FIG. 1A for simplicity. The discussion of GAA FET 105A applies to GAA FET 105B, unless mentioned otherwise.

Referring to FIGS. 1A and 1B, semiconductor device 100 can be formed on a substrate 110. Substrate 110 can include a semiconductor material, such as silicon, germanium (Ge), silicon germanium (SiGe), a silicon-on-insulator (SOI) structure, and a combination thereof. Further, substrate 110 can be doped with p-type dopants (e.g., boron, indium, aluminum, or gallium) or n-type dopants (e.g., phosphorus or arsenic).

Each of GAA FETs 105A and 105B include a gate structure 115, which surrounds nanostructured channel layers 120. By way of example and not limitation, each gate structure 115 includes interfacial oxide layer 115a and dielectric layer 115b (also referred to herein as “high-k dielectric layer”). In addition, each gate structure 115 includes gate electrode 115c, which further includes capping layers, one or more work function metal layers, and a metal fill layer, not shown in FIG. 1B for simplicity.

Further, GAA FETs 105A and 105B include source/drain (S/D) epitaxial structures 125 in contact with nanostructured channel layers 120. Each S/D epitaxial structure 125 may include one or more doped epitaxial layers, which are successively formed on substrate 110. In some embodiments, S/D epitaxial structures 125 are electrically isolated from gate structures 115 via inner spacers 130. Inner spacers 130 further separate nanostructured channel layers 120 in the vertical direction (e.g., along the z-direction) as shown in FIG. 1B.

In some embodiments, each inner spacer 130 includes an inner spacer layer 130a with an air gap 130b. In some embodiments, air gap 130b is formed between inner spacer 130 and S/D epitaxial structure 125. In some embodiments, air gap 130b reduces the dielectric constant of inner spacer 130. This is because air has a dielectric constant of 1, which is lower than that of inner spacer layer 130 a (e.g., between about 3.7 and about 5.2). In some embodiments, inner spacer layer 130a can be formed of the flowable polymer, which can include one or more of oxygen, silicon, nitrogen, hydrogen, or carbon. In some embodiments, a higher O:Si ratio in the polymer layer can increase the dielectric constant. For example, a polymer layer with an O:Si ratio of about 1.4 can have a higher dielectric constant than a polymer layer with an O:Si ratio of about 0.7. In some embodiments, increasing the amount of carbon can increase the density and etch resistance of the polymer layer. The inner spacers formed of the polymer layer can be seamless. Owing to an absence of seams, the polymer layer can have a higher etch resistance to a post deposition etch process directed to removing the polymer layer outside the spacer cavities. In some embodiments, inner spacers 130 can reduce parasitic capacitances formed between gate structures 115 and S/D epitaxial structures 125.

In some embodiments, sidewall surfaces of gate structures 115 in GAA FETs 105A and 105B are covered by one or more outer gate spacers. For example, as shown in FIG. 1B, sidewall surfaces of gate structures 115 are covered by outer gate spacer 135a, which provides electrical isolation and protection to gate structures 115 during the formation of S/D contacts (not shown in FIG. 1B). According to some embodiments, the S/D contacts are disposed on S/D epitaxial structures 125, adjacent to and between gate structures 115. In some embodiments, etch stop layer (ESL) 135b can extend over S/D epitaxial structures 125 as shown in FIG. 1B. In some embodiments, ESL 135b is surrounded by an interlayer dielectric (ILD) 140, which provides additional electrical isolation to the conductive components of GAA FETs 105A and 105B.

In some embodiments, GAA FETs 105A and 105B can be n-type or p-type (e.g., pFETs or nFETs). Additional GAA FETs, similar to the GAA FETs shown in FIG. 1B, can be formed over substrate 110. By way of example and not limitation, p-type GAA FETs include S/D epitaxial structures 125 with boron-doped (B-doped) silicon-germanium (SiGe:B) layers, B-doped germanium (Ge:B) layers, B-doped germanium-tin (GeSn:B) layers, or combinations thereof. In some embodiments, n-type GAA FETs include S/D epitaxial structures 125 with arsenic (As)-doped silicon layers (Si:As), phosphorous (P)-doped silicon layers (Si:P), carbon-doped silicon layers (Si:C), or combinations thereof. By way of example and not limitation, S/D epitaxial structures 125 are grown directly on top surfaces of substrate 110. GAA FETs 105A and 105B can be separated by shallow trench isolation (STI) regions as shown in FIG. 1A. STI regions 116 are not visible in cross-sectional view of FIG. 1B.

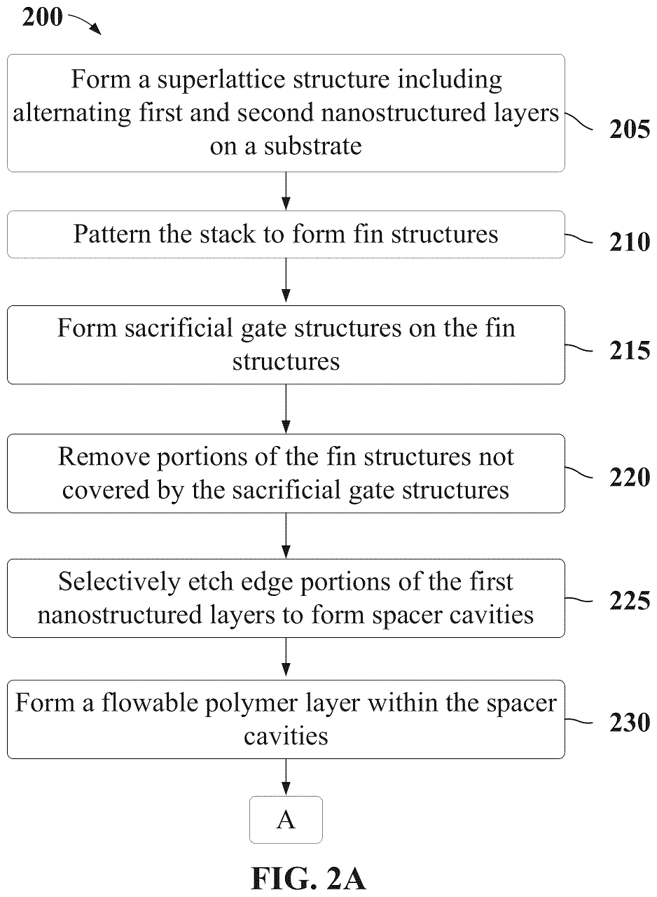

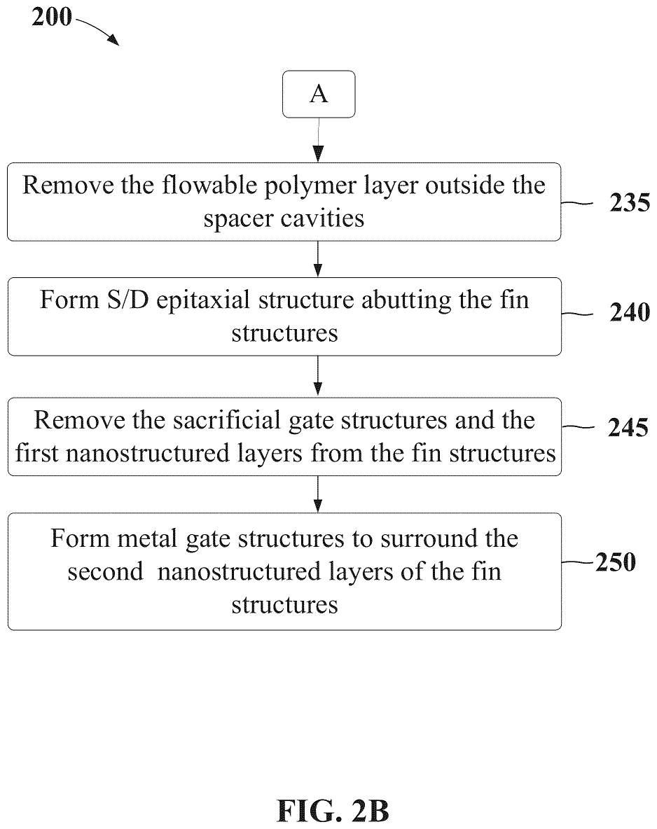

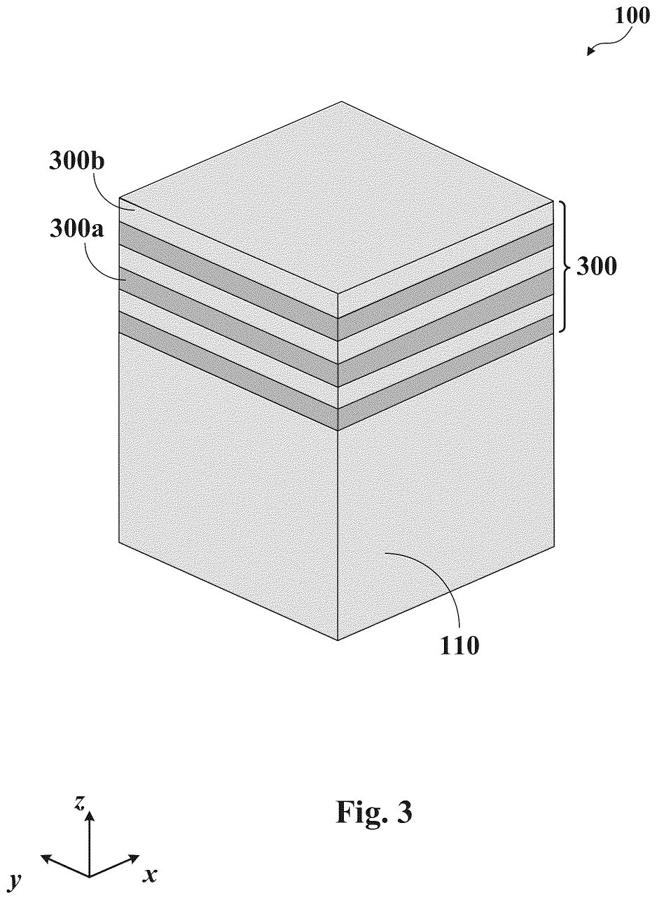

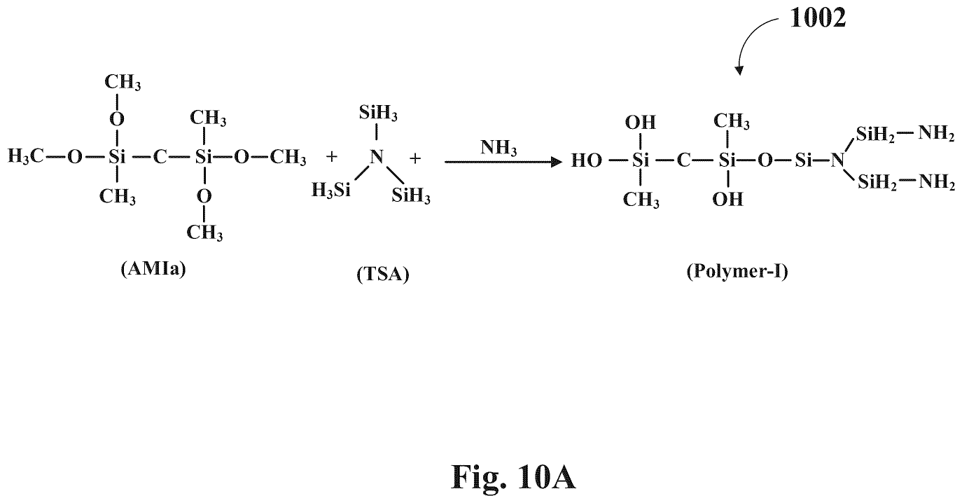

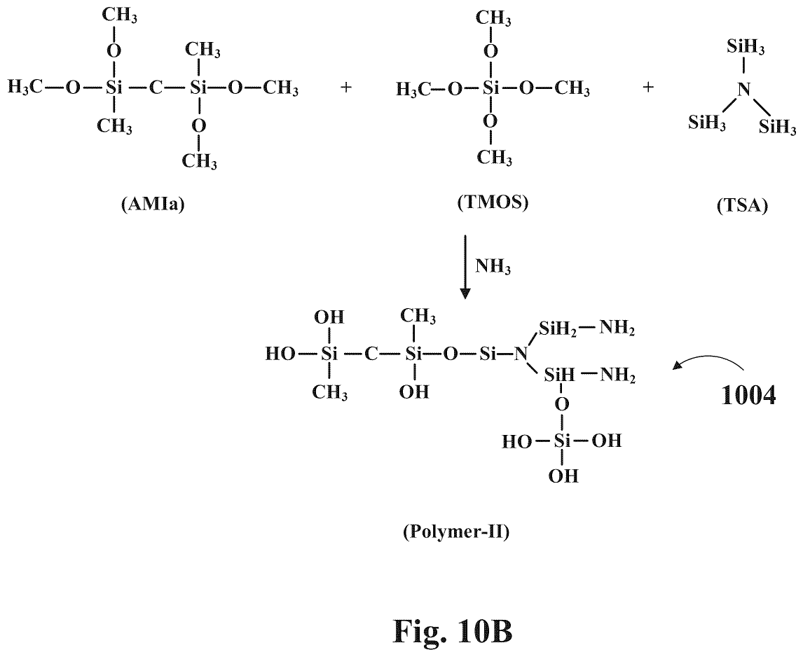

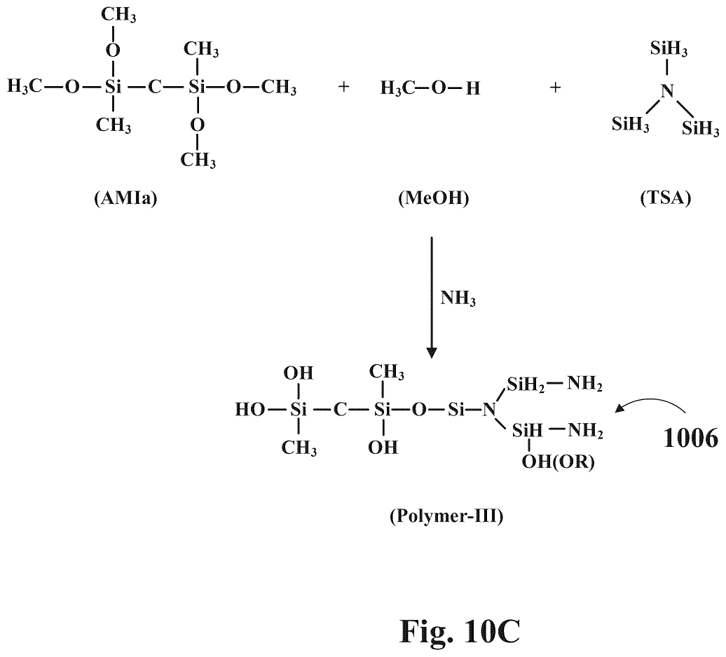

According to some embodiments, FIGS. 2A and 2B are flowcharts of a fabrication method 200 for the formation of inner spacers 130 in GAA FETs 105A and 105B shown in FIG. 1B. Other fabrication operations can be performed between the various operations of method 200 and are omitted merely for clarity. This disclosure is not limited to this operational description and additional operations may be performed. Moreover, not all operations may be necessary to perform the disclosure provided herein. Additionally, some of the operations may be performed simultaneously, or in a different order than the one shown in FIGS. 2A and 2B. In some embodiments, one or more other operations may be performed in addition to or in place of the presently described operations. For illustrative purposes, method 200 is described with reference to the structures shown in FIGS. 3-6, 7A-9A, 7B-9B, 9C, and 11-15. FIGS. 10A, 10B, and 10C illustrate chemical reactions related to the formation of the flowable polymer.

In referring to FIG. 2A, method 200 begins with operation 205 for forming a superlattice structure including alternating first and second nanostructured layers on a substrate (e.g., on substrate 110). In some embodiments, the substrate (e.g., substrate 110) includes silicon or another elementary semiconductor, such as germanium (Ge). In some embodiments, the substrate includes a compound semiconductor like silicon carbide (SiC), gallium arsenide (GaAs), gallium phosphide (GaP), indium phosphide (InP), indium arsenide (InAs), or indium antimonide (InSb). In some embodiments, the substrate includes an alloy semiconductor, like silicon germanium (SiGe), gallium arsenide phosphide (GaAsP), aluminum indium arsenide (AlInAs), aluminum gallium arsenide (AlGaAs), gallium indium arsenide (GaInAs), gallium indium phosphide (GaInP), or gallium indium arsenide phosphide (GaInAsP). In some embodiments, the substrate includes any combination of the aforementioned materials. In some embodiments, substrate 110 is intrinsic (e.g., un-doped) or doped. In some embodiments, substrate 110 includes doped and un-doped regions.

With reference to FIG. 3, during operation 205, superlattice structure 300 including alternating first and second nanostructured layers 300a and 300b can be formed on substrate 110. In some embodiments, first and second nanostructured layers 300a and 300b can be formed on exposed top surfaces of substrate 110. In some embodiments, first nanostructured layers 300a can be sacrificial nanostructured layers, which are removed later in the fabrication process. Second nanostructured layers 300b can be nanostructured channel layers and correspond to nanostructured channel layers 120 shown in FIG. 1. In some embodiments, the material of first nanostructured layers 300a in superlattice structure 300 is selected so that first nanostructured layers 300a can be selectively removed via etching from superlattice structure 300 without removing second nanostructured layers 300b. For example, first nanostructured layers can be SiGe layers and second nanostructured layers 300b can be Si layers. In some embodiments, the deposition sequence begins with the type of the nanostructured layers to be removed—for example, in this case with first nanostructured layer 300a.

First and second nanostructured layers 300a and 300b can be grown by any suitable method. For example, first and second nanostructured layers 300a and 300b can be grown with a chemical vapor deposition (CVD) process with precursor gases like silane (SiH₄), disilane (Si₂H₆), dichlorosilane (SiH₂Cl₂), germane (GeH₄), digermane (Ge₂H₆), other suitable gases, or combinations thereof. In some embodiments, first nanostructured layers 300a can include a Ge concentration, for example, between about 15 at. % and about 40 at. %, while second nanostructured layers 300b can be substantially germanium-free—e.g., have a Ge concentration for example, less than about 1 at. %. In some embodiments, second nanostructured layers 300b, which correspond to nanostructured channel layers 120 in FIG. 1, form the channel region of GAA FETs 105A and 105B and can be lightly doped or un-doped. If lightly doped, the doping level of second nanostructured layers 300b can be, for example, less than about 1×10¹³ atoms/cm³. First and second nanostructured layers 300a and 300b can be sequentially deposited without a vacuum break (e.g., in-situ) to avoid oxidation and the formation of any intervening layers between first and second nanostructured layers 300a and 300b. In some embodiments, first nanostructured layers 300a can be doped to increase their etching selectivity compared to second nanostructured layers 300b in a subsequent etching operation.

In some embodiments, the thickness of first nanostructured layers 300a controls the spacing between every other second nanostructured layer 300b in superlattice structure 300. The thickness of first and second nanostructured layers 300a and 300b can range, for example, from about 6 nm to about 16 nm. Since first and second nanostructured layers 300 a and 300 b are grown individually, the thickness of each nanostructured layer can be adjusted independently based, for example, on the deposition time during growth. In some embodiments, additional or fewer number of first and second nanostructured layers 300a and 300b can be formed in superlattice structure 300. In some embodiments, the total number of nanostructured layers is 2n where n is the number of first nanostructured layers 300a or the number of second nanostructured layers 300b in superlattice structure 300.

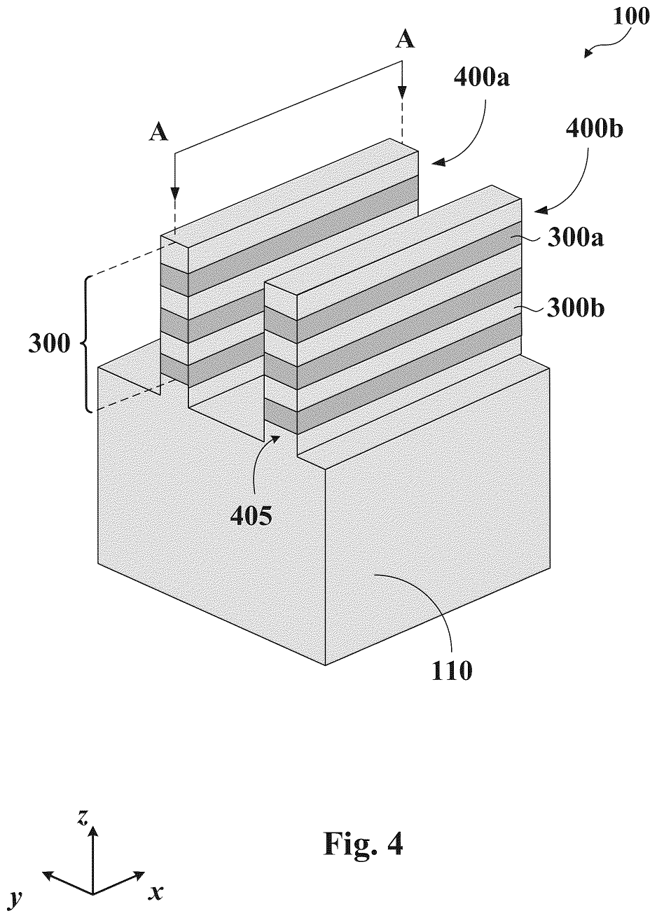

In referring to FIG. 2A, method 200 continues with operation 210 during which superlattice structure 300 is patterned to form fin structures. For example, as shown in FIG. 4, superlattice structure 300 can be patterned and etched to form fin structures 400a and 400b. As shown in FIG. 4, fin structures 400a and 400b can include first nanostructured layers 300b and nanostructured channel layers 120. In some embodiments, superlattice structure 300 can be patterned to form fin structures with a width along the y-direction and a length along the x-direction. In some embodiments, a portion of substrate 110 can also be etched to form pedestal structure 405 under each of the fin structures 400a and 400b. Since fin structures 400a and 400b and pedestal structures 405 are formed with the same patterning process, fin structures 400a and 400b and pedestal structures 405 are substantially aligned to each other. For example, sidewall surfaces of fin structures 400a and 400b in the x-z plane and y-z plane are substantially aligned to respective sidewall surfaces of pedestal structures 405 as shown in FIG. 4.

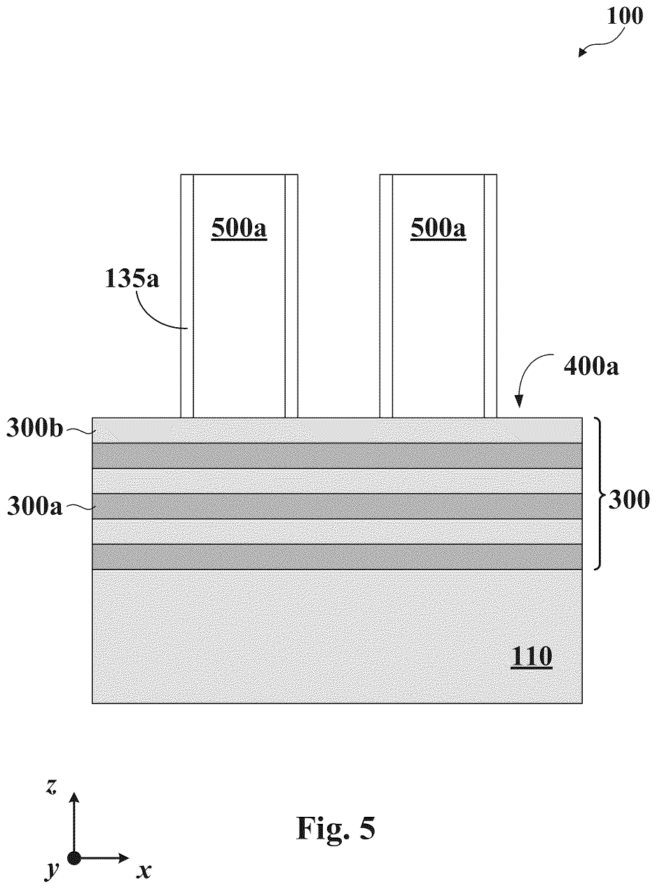

In referring to FIG. 2A, method 200 continues with operation 215 during which sacrificial gate structures are formed on the fin structures. For example, as shown in FIG. 5 which is a cross-sectional view of FIG. 4 along cut-line AA, sacrificial gate structures 500a can be formed surrounding fin structures 400a. Forming sacrificial gate structures 500a can include epitaxially forming polysilicon structures covering sidewalls and top surfaces of fin structure 400a. Outer gate spacers 135a can be formed on either side of sacrificial gate structures 500a. Similar sacrificial gate structures can be formed surrounding fin structure 400b (not shown). In some embodiments, sacrificial gate structures 500a can be formed on an interfacial gate oxide layer (not shown for simplicity). In some embodiments, sacrificial gate structures 500a are replaced by gate structures 115 shown in FIG. 1B during a gate replacement process.

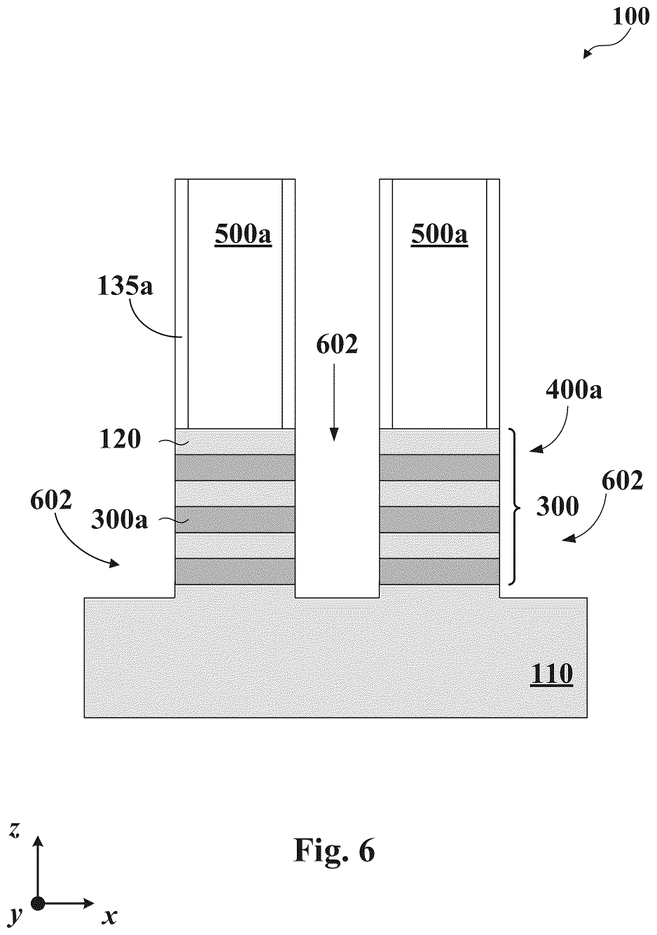

Referring to FIG. 2A, in operation 220, S/D openings are formed in the fin structures. For example, with reference to FIG. 6, S/D openings 602 can be formed within fin structure 400a. S/D openings 602 can be formed within fin structure 400a by etching portions of fin structure 400a not underlying sacrificial gate structures 500a. In some embodiments, as shown in FIG. 6, a portion of substrate 110 can be etched along with fin structure 400a to form a recess within substrate 110.

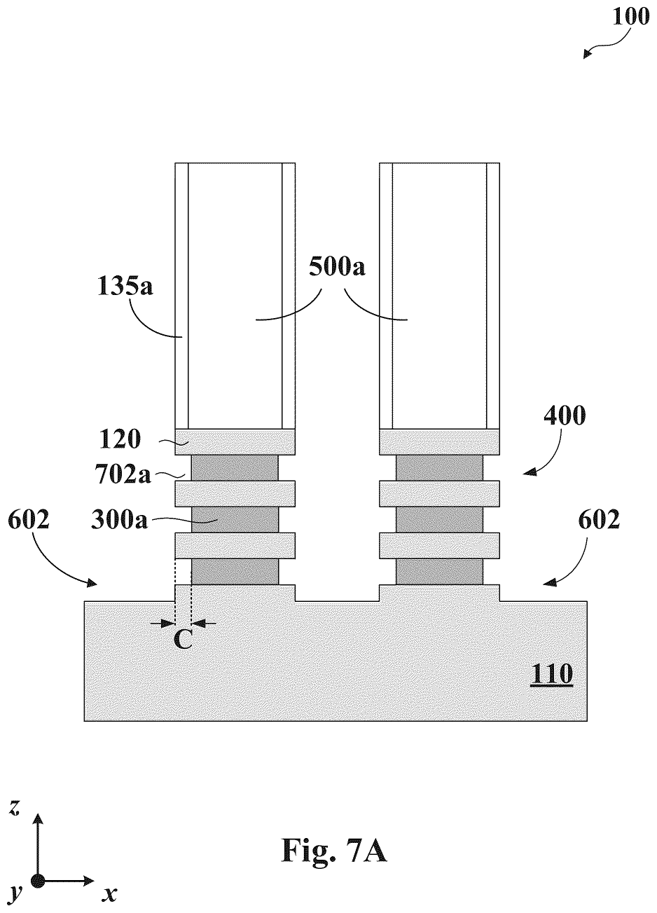

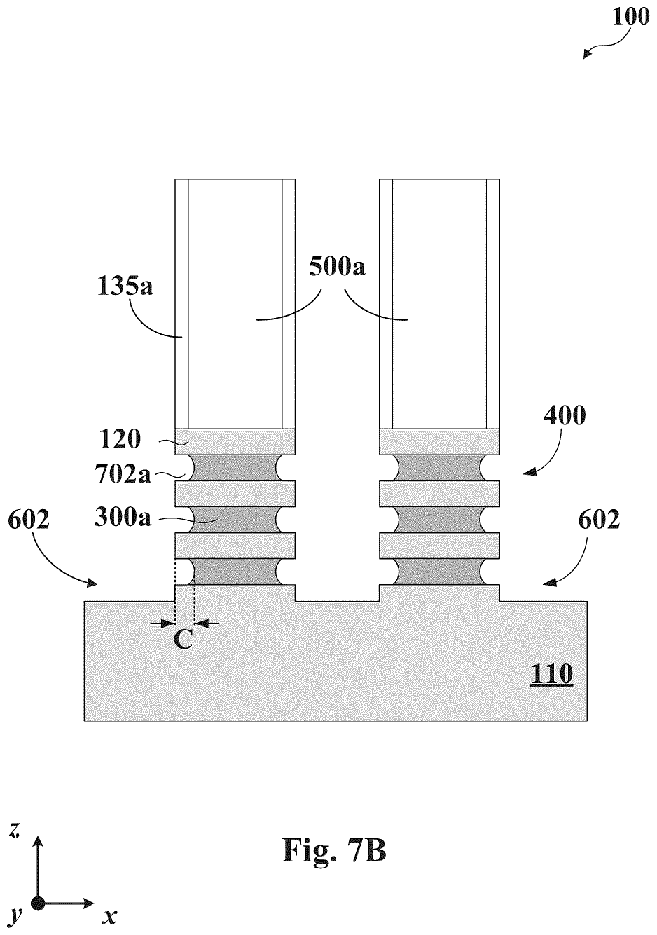

With reference to FIG. 2A, in operation 225, spacer cavities can be formed on edge portions of first nanostructured layers. For example, as shown in FIG. 7A, spacer cavities 702a can be formed by etching first nanostructured layers 300a along the x-axis so that first nanostructured layers 300a are recessed with respect to nanostructured channel layer 120. In some embodiments, as shown in FIG. 7A, etched first nanostructured layers 300a can have a linear sidewall profile. However, in some embodiments, as shown in FIG. 7B, etched first nanostructured layers 300a can have curved sidewall profiles. The spacer cavities can have a depth C along the x-direction. In some embodiments, depth C can be in the range of about 4 nm and about 8 nm. According to some embodiments, spacer cavities with a width, for example, less than about 9 nm result in inner spacers 130 that are too thin to provide adequate electrical isolation between gate structures 115 and S/D epitaxial structures 125 shown in FIG. 1. On the other hand, spacer cavities with a width C greater than, for example, about 6 nm result in inner spacer layer 130a that reduces the gate length of the resulting transistor structures (e.g., GAA FETs 105A and 105B).

In some embodiments, the spacer cavities can be formed with a dry etching process selective towards first nanostructured layers 300a. If first nanostructured layers 300a are formed of SiGe and nanostructured channel layers 120 are formed of Si, halogen-based chemistries can be used. Halogen-based chemistries can exhibit a high etching selectivity towards Ge and a low etching selectivity towards Si. Therefore, halogen gases etch Ge-containing layers, such as first nanostructured layers 300a, at a higher etching rate than substantially Ge-free layers like nanostructured channel layers 120. In some embodiments, the halogen-based chemistries include fluorine-based and/or chlorine-based gases. Alternatively, a wet etching chemistry with high selectivity towards SiGe can be used. By way of example and not limitation, a wet etching chemistry may include buffered hydrofluoric acid (BHF), hydrofluoric acid (HF), hydrofluoric nitric acid (HNA), phosphoric acid, HF diluted by ethylene glycol (HFEG), hydrochloric acid (HCl), or any combination thereof. The aforementioned etching processes can be timed so that the desired amount of SiGe is removed.

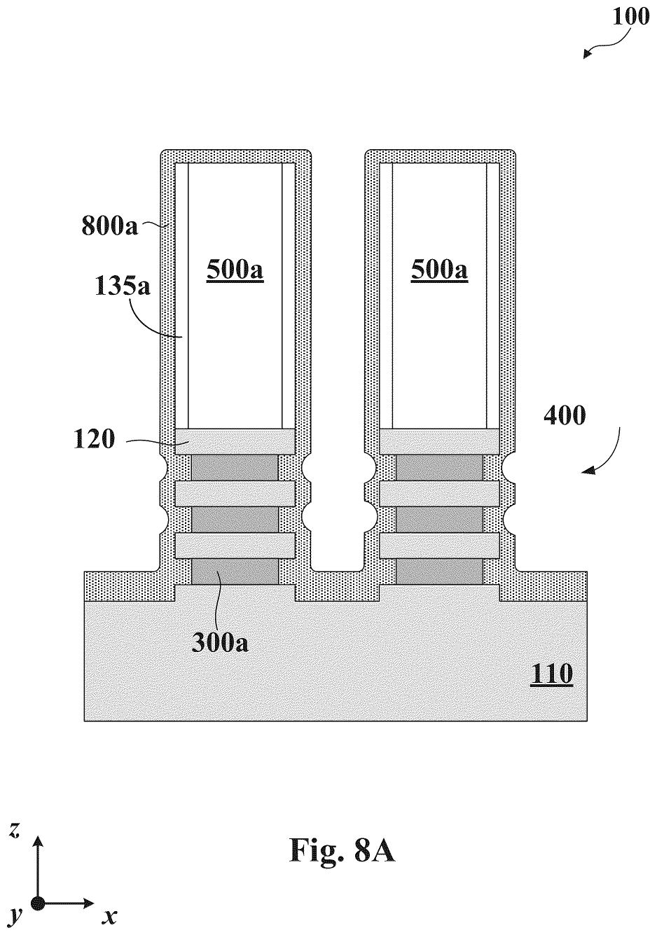

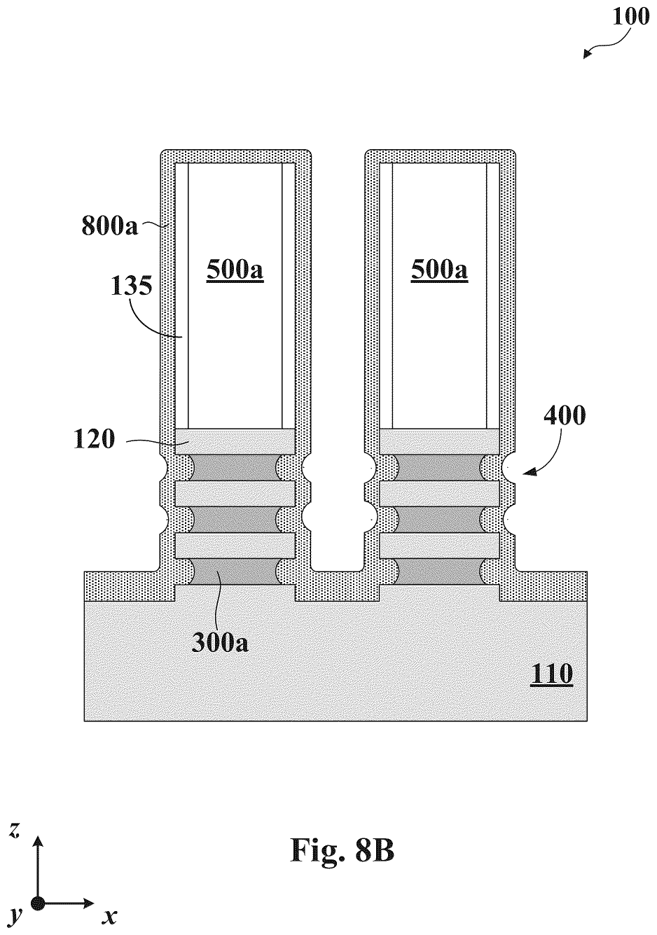

With reference to FIG. 2A, the method then proceeds to operation 230 during which a polymer layer can be formed within the spacer cavities. In some embodiments, as shown in FIGS. 8A and 8B, polymer layer 800a can be formed on (a) an exposed top surface of substrate 110, (b) within spacer cavities 702a, (c) on vertical sidewall surfaces of nanostructured channel layers 120, and (d) on top and sidewall surfaces of sacrificial gate structure 500a, as shown in FIGS. 8A and 8B.

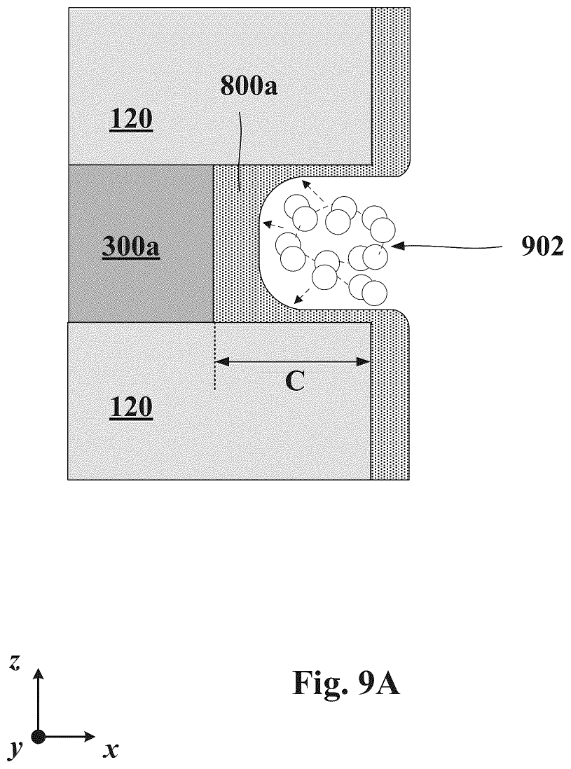

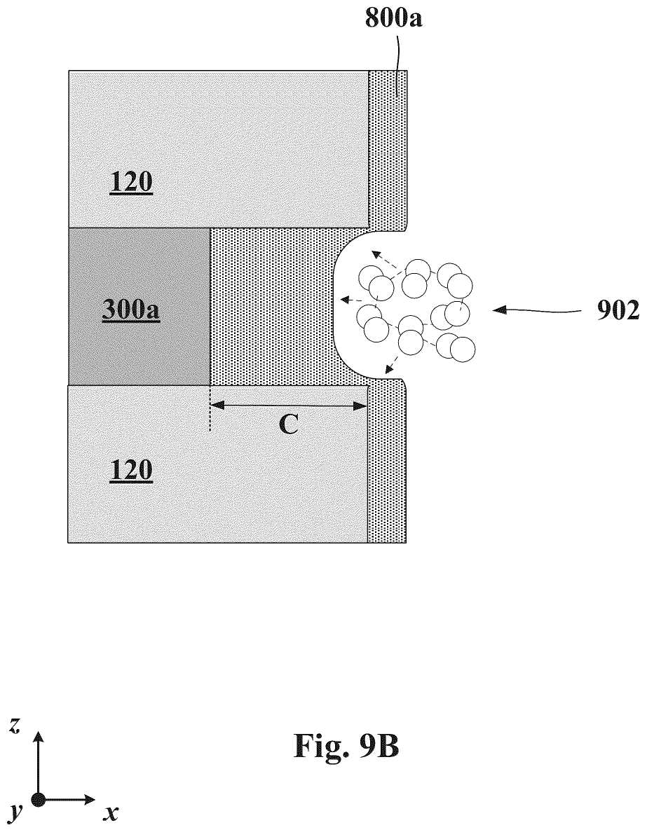

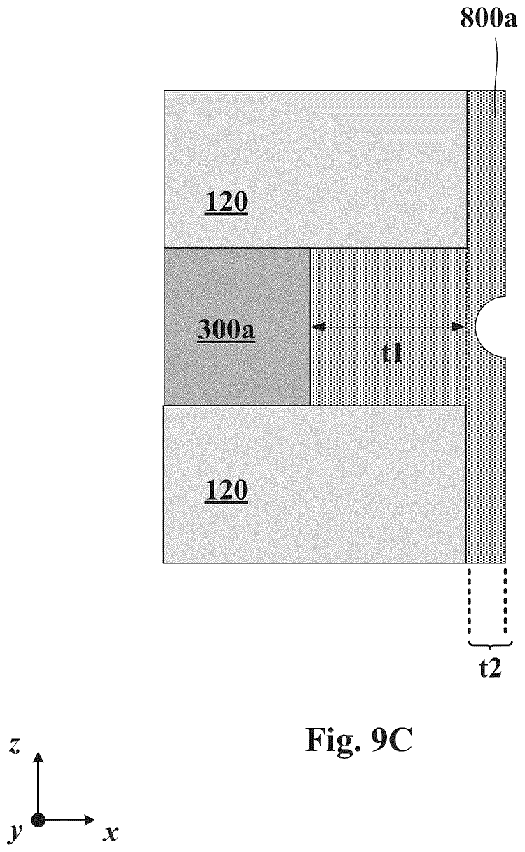

FIGS. 9A-9C illustrate the formation of polymer layer 800a (also referred to herein as “flowable polymer”) within spacer cavities 702a. In some embodiments, deposition of the polymer layer can be performed within a chemical vapor deposition chamber. Precursors, such as an organosilicon compound, trisilylamine (TSA), and ammonia (NH₃), can be flowed into the chemical vapor deposition chamber. In some embodiments, the organosilicon compound can be AMIa. The organosilicon compound, TSA, and NH₃ (which are in vapor form) can react to form polymer vapors. The polymer vapors can condense to form the flowable polymer. In some embodiments, the polymer layer can be formed by condensation of polymer vapors 902 within spacer cavities 702a and on vertical sidewalls of nanostructured channel layers 120, as shown in FIGS. 9A and 9B. To promote the condensation of polymer vapors, the temperature within the chamber can be lowered to, for example, about 5° C. The condensation temperature can vary based on the polymer species. The condensation of polymer vapors 902 can also be affected by a molecular size of polymer vapors 902. Large-sized polymer molecules with longer and branched molecular chains, having a large surface area, are attracted to one another by Vander-Waal forces. Polymer molecules forming polymer vapors 902 have long and branched molecular chains, and can therefore be attracted by Vander-Waal forces, which can bring a large number of polymer molecules closer to subsequently condense. During the deposition phase, vapor pressure within spacer cavities 702a is different from the vapor pressure outside spacer cavities 702a, for example, on the vertical sidewalls of first nanostructured layers 300a. The vapor pressure outside spacer cavities 702a can be substantially equal to the saturation vapor pressure. Until the vapor pressure within spacer cavities 702a is less than the saturation vapor pressure, polymer vapors 902 can continue to condense within spacer cavities 702a, as shown in FIGS. 9A and 9B. When the vapor pressure within the cavity is substantially equal to the saturation vapor pressure, the condensation process ends, as shown in FIG. 9C. During the condensation process, polymer vapors 902 can condense to fill spacer cavities 702a with flowable polymer 800a, which can be in a semi-solid or flowable state. Spacer cavities 702a, which are narrow channels, can act as capillaries within which the flowable polymer 800a can be drawn due to capillary action. For example, a width of spacer cavities 702a can be between about 4 nm and about 8 nm. Since the capillary action is predominantly responsible for filling spacer cavities 702a with flowable polymer 800a, thickness t1 of flowable polymer 800a within spacer cavity 702a is greater than thickness t2 of flowable polymer 800a deposited on the vertical sidewalls of nanostructured channel layer 120, as shown in FIG. 9C. In some embodiments, thickness t1 can be in between about 4 nm and about 8 nm, and thickness t2 can be between about 1 nm and about 3 nm.

In some embodiments, flowable polymer 800a can be drawn into spacer cavities 702a due to adhesive forces and surface tension. Flowable polymer 800a with increased surface tension can fill spacer cavities 702a evenly and rapidly. In some embodiments, the surface tension can be increased by flowing ammonia (NH₃). On the other hand, in some embodiments, a rate at which spacer cavities 702a are filled with flowable polymer 800a can vary inversely with a viscosity of flowable polymer 800a. In some embodiments, the viscosity of flowable polymer 800a can be directly proportional to a size of the molecules or molecular weight of molecules forming flowable polymer 800a. Therefore, to achieve a sufficient filling rate, molecular weight of molecules forming flowable polymer 800a can be, for example, between about 100 g/mol and about 1000 g/mol.

In some embodiments, flowable polymer 800a can be formed by reacting the organosilicon compound, for example polymer precursor AMIa, with trisilylamine (TSA) and ammonia (NH₃). As shown in FIG. 10A, in some embodiments, AMIa vapors can react with TSA vapors and NH₃ vapors to form polymer-I 1002. Polymer-I vapors represented by polymer vapors 902 can condense within spacer cavities 702a to form liquid polymer-I 1002 (represented herein by flowable polymer 800a, as shown in FIGS. 9A and 9B). In some embodiments, polymer-I vapors can condense at a temperature between about 0° C. and about 100° C. For example, polymer-I vapors can condense at a temperature of about 5° C. Post deposition, polymer-I 1002 can be cured or solidified by a plasma treatment. In some embodiments, the plasma treatment can include heating flowable polymer-I 1002 to a temperature between about 450° C. to about 600° C., in a hydrogen (H₂) environment, to evaporate solvents and harden polymer-I 1002. For example, polymer-I 1002 can be plasma treated in an H₂ environment at about 500° C. In some embodiments, polymer-I 1002 can include Si, C, O, and N in the ratio of about 36:19:25:20. In some embodiments, polymer-I 1002 can have an O:Si ratio of about 0.7.

In some embodiments, polymer vapor 902 can be formed by reacting the organosilicon compound, for example polymer precursor AMIa, with TSA, trimethyl oxisilicate (TMOS), and NH₃. As shown in FIG. 10B, AMIa vapors can react with TSA vapors, TMOS vapors, and NH₃ vapors to form polymer-II 1004. Polymer-II vapors represented by polymer vapors 902 can condense within spacer cavities 702a to form polymer-II 1004 (represented herein by flowable polymer 800a, as shown in FIGS. 9A and 9B). Polymer-II vapors can condense at a temperature between about 0° C. and about 100° C. For example, polymer-II vapors can condense at a temperature of about 5° C. Post deposition, polymer-II 1004 can be cured or solidified by a plasma treatment. In some embodiments, the plasma treatment can be performed at a temperature between about 450° C. and about 600° C. in a hydrogen (H ₂) environment to evaporate solvents and harden polymer-II 1004. For example, polymer-II 1004 can be plasma treated in an H₂ environment at about 500° C. In some embodiments, polymer-II 1004 can include Si, C, O, and N in the ratio of about 30:13:44:13. In some embodiments, polymer-II 1004 can have an O:Si ratio of about 1:4. Due to the higher oxygen content in polymer-II 1004 compared to polymer-I 1002, polymer-II 1004 can have a lower dielectric constant. Polymer-II can have a dielectric constant of, for example, about 4.5 and polymer-I can have a dielectric constant of, for example, about 4.8.

In some embodiments, polymer vapor 902 can be formed by reacting the organosilicon compound, for example polymer precursor AMIa, with TSA, methanol (MeOH) and NH₃. As shown in FIG. 10C, AMIa vapors can react with TSA vapors, MeOH vapors, and NH₃ vapors to form polymer-III 1006. Polymer-III vapors represented by polymer vapors 902 can condense within spacer cavities 702a to form polymer-III 1006 (represented herein by flowable polymer 800a, as shown in FIGS. 9A and 9B). Polymer-III vapors can condense at a temperature between about 0° C. and about 100° C. For example, polymer-III vapors can condense at a temperature of about 5° C. Post deposition, polymer-III 1006 can be cured or solidified by a hydrogen-based plasma treatment. In some embodiments, the hydrogen-based plasma treatment can include heating polymer-III 1006 to a temperature between about 450° C. and about 600° C. in a hydrogen (H₂) environment to evaporate solvents and harden polymer-III 1006. For example, polymer-III 1006 can be heated to a temperature of about 500° C. in a hydrogen (H₂) environment.. In some embodiments, polymer-III 1006 can have Si, C, O, and N in the ratio of about 30:10:50:10. In some embodiments, polymer-III 1006 can have an O:Si ratio of about 1:2. Polymer-III can have a lower dielectric constant compare to polymer-II. Polymer-III 1006 can have a dielectric constant of, for example, about 4.0 and polymer-II 1004 can have a dielectric constant of, for example, about 4.5.

Due to the higher carbon content in polymer-III 1006 compared to polymer-I 1002 and polymer-II 1004, polymer-III 1006 can have a higher etch resistance. In some embodiments, a higher number of —OR groups in the polymer layer can reduce leakage. This implies that inner spacers formed of a polymer layer with a large number of-OR groups, such as polymer-III 1006, can reduce leakage current between S/D epitaxial structures and gate structures.

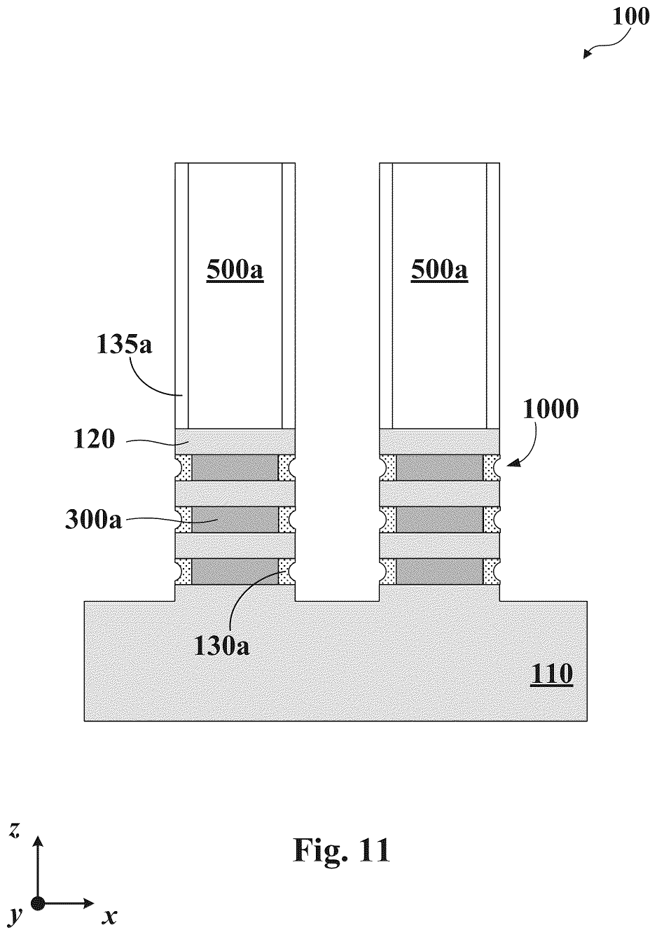

With reference to FIG. 2B, in operation 235, the polymer layer formed outside the spacer cavities can be removed. In some embodiments, polymer layer 800a formed outside spacer cavities 702a and on sidewall surfaces of nanostructured channel layers 120, as shown in FIGS. 8A and 8B, can be etched to form inner spacer layer 130a, as shown in FIG. 11. Polymer layer 800a can be etched using a dry or wet etching process. The etched profile of polymer layer 800a can include an indentation or a dip in a sidewall of inner spacer layer 130a, in a region of spacer cavities, as shown in FIG. 11.

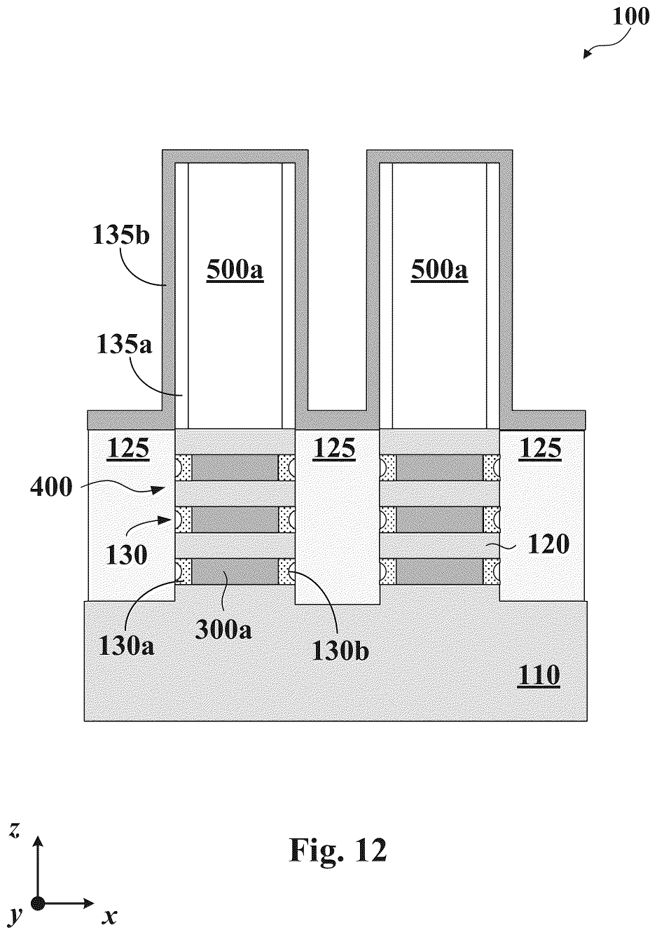

With reference to FIG. 2B, in operation 240, S/D epitaxial structures 125 are formed on substrate 110. The formation of S/D epitaxial structures 125 can include epitaxially growing n-type or p-type semiconductor materials within S/D openings, as shown in FIG. 12.

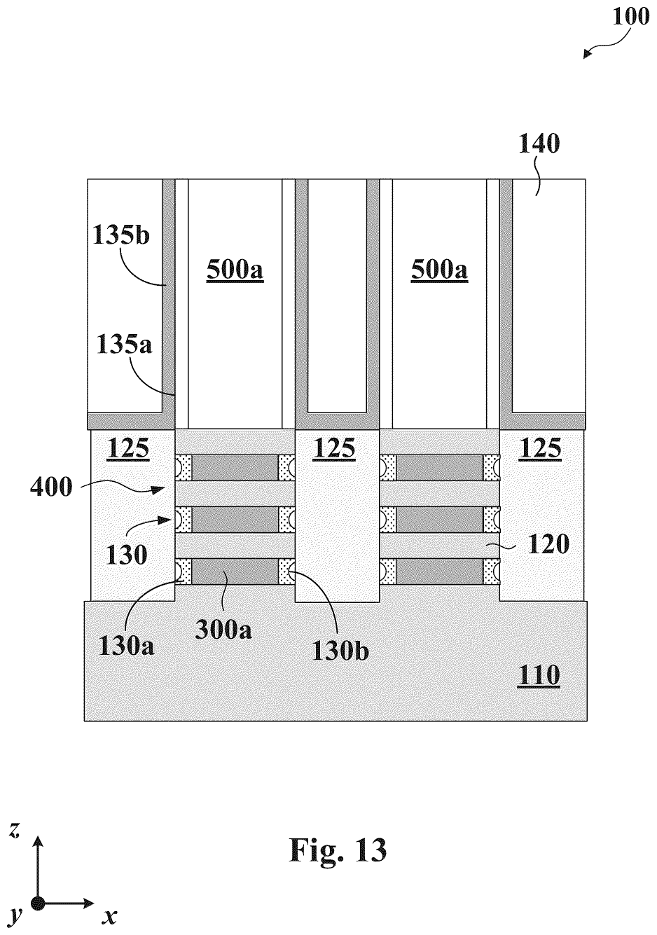

After the formation of S/D epitaxial structures 125, the indentation or dip in the sidewall of inner spacer 130a is sealed to form air gap 130b shown in FIGS. 12 and 13. As discussed above, inner spacers 130 isolate first nanostructured layers 300a from S/D epitaxial structures 125. At the same time, nanostructured channel layers 120 are in physical contact with S/D epitaxial structures 125.

In some embodiments, following the formation of S/D epitaxial structures 125, etch stop layer (ESL) is formed to protect S/D epitaxial structures 125 from oxidation during the subsequent formation of ILD 140, as shown in FIG. 12. By way of example and not limitation, ESL 135b can include an oxygen-free dielectric, such as SiN or SiCN. In some embodiments, the material of ESL 135b is blanket deposited on sacrificial gate structures 500a and S/D epitaxial structures 125 as shown in FIG. 13. By way of example and not limitation, ESL 135b can be deposited with a conformal process, such as a plasma-assisted CVD (PECVD) process and a plasma-assisted ALD (PEALD) process.

After the formation of ESL 135b, ILD 140 can be deposited and planarized so that top surfaces of ILD 140 are substantially coplanar with top surfaces of polysilicon structure 500a, as shown in FIG. 13. In some embodiments, ILD 140 includes a single dielectric or a stack of dielectrics. In some embodiments, ILD 140 is a silicon oxide based dielectric that includes other elements, such as nitrogen and/or hydrogen.

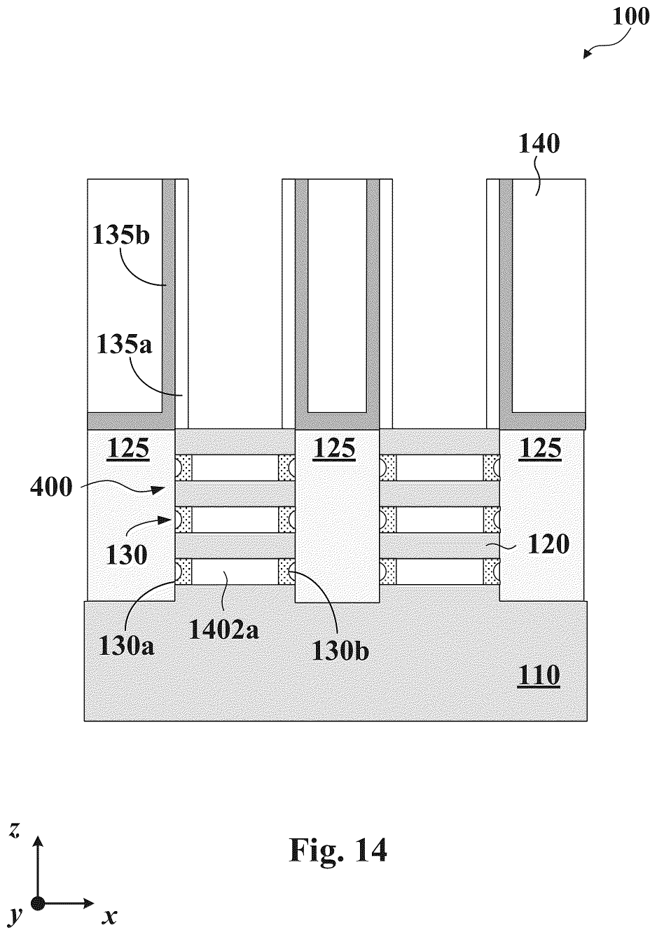

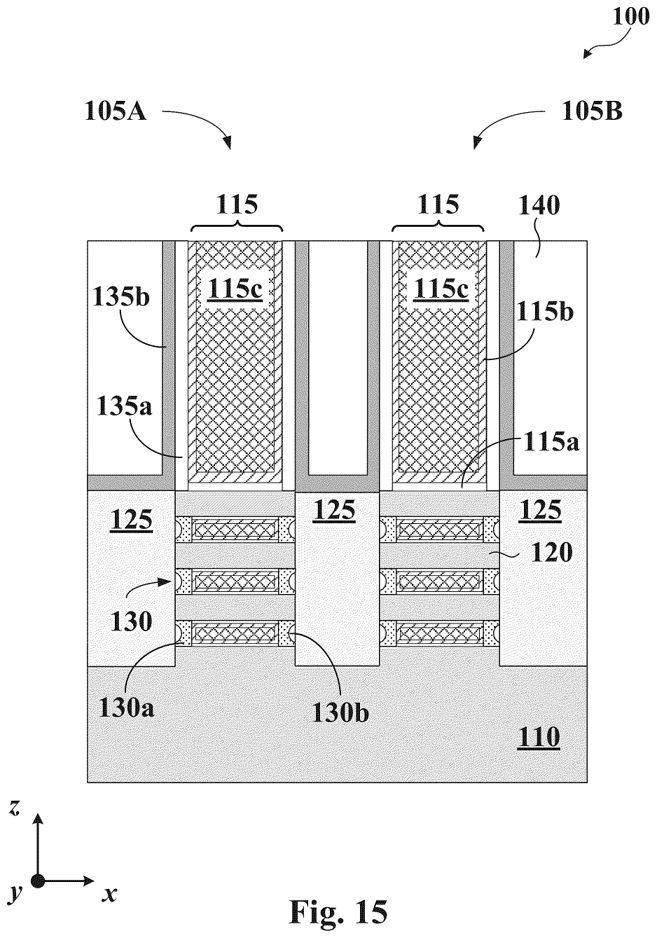

In referring to FIG. 2B, method 200 continues with operation 245 and the process of removing sacrificial gate structures 500a and first nanostructured layers 300a from fin structures 400. By way of example and not limitation, removal of sacrificial gate structures 500a and first nanostructured layers 300a is achieved with one or more etching operations, which may include dry etching, wet etching, or combinations thereof. In some embodiments, where first nanostructured layers 300a are formed of SiGe and nanostructured channel layers are formed of Si, first nanostructured layers 300a are removed with a dry etching process selective to SiGe to form openings 1402a, as shown in FIG. 14. For example, halogen-based chemistries exhibit higher etching selectivity towards Ge compared to Si. Therefore, halogen gases etch Ge-containing layers (e.g., first nanostructured layers 300a) at a higher etching rate than substantially Ge-free layers (e.g., nanostructured channel layers 120). In some embodiments, the halogen-based chemistry includes fluorine-based and/or chlorine-based gases. Alternatively, a wet etching chemistry with high selectivity towards SiGe can be used. By way of example and not limitation, a wet etching chemistry can include Sulphuric peroxide mixture (SPM) or ammonia-peroxide mixture (APM) solutions. In some embodiments, the etching chemistry used in operation 245 does not remove nanostructured channel layers 120, inner spacers 130, outer gate spacer 135a, and ESL 135b, as shown in FIG. 15.

In referring to FIG. 2B, method 200 continues with operation 250 and the process of forming metal gate structures (e.g., like the gate structures 115 shown in FIG. 1B) to surround nanostructured channel layers 120 of fin structures 400a and 400b. For example, the layers of gate structures 115 can be formed sequentially on the exposed surfaces of nanostructured channel layers 120 to form GAA FETs 105A and 105B shown in FIG. 15. As discussed above, the metal gate structures (e.g., like the gate structures 115 shown in FIG. 15) are electrically isolated from S/D epitaxial structures 125 by inner spacers 130. FIG. 15 shows the structure of FIG. 14 after operation 250 and the formation of gate structures 115. In some embodiments, the GAA FETs shown in FIGS. 1B and 15 are identical. In some embodiments, air gaps 130b further reduce the parasitic capacitance formed between gate structures 115 and S/D epitaxial structures 125.

The embodiments described herein are directed to inner spacer 130 that does not include a seam or an air gap and method 200 of forming the same. Inner spacers 130 are formed of flowable polymer layer 800a (also referred to herein as “polymer layer 800a”). In some embodiments, polymer layer 800 a can have a dielectric constant of less than about 4.0. This helps reduce the parasitic capacitance between S/D epitaxial structure 125 and gate structure 115. The dielectric constant of polymer layer 800a can be further tuned by varying the ratio of oxygen to silicon (O: Si) in polymer layer 800a. An increase in O: Si ratio and/or a decrease in a nitrogen content in polymer layer 800a can reduce the dielectric constant of polymer layer 800a. On the other hand, an increase in carbon content can reduce leakage current between S/D epitaxial structures 125 and gate structures 115. An increased carbon content can also increase a density of polymer layer 800a.

Method 200 of forming polymer layer 800a forms a thicker polymer layer within spacer cavities 702a than on the sidewalls of nanostructured channel layers 300b outside spacer cavities 702a, according to some embodiments. This reduces the etching time for etching polymer layer 800a outside spacer cavities 702a (on the sidewalls of nanostructured channel layers 300b). The disclosed method of forming polymer-based inner spacers 130 prevents formation of seams or air gaps within inner spacer layer 130a.

In some embodiments, a method includes forming a fin structure with a plurality of alternating first and second nanostructured layers, etching side portions of each of the first nanostructured layers to form a recess at an end of each first nanostructured layer, and exposing the recess to a vapor comprising a polymer precursor. The method further includes depositing a polymer layer in the recess and on sidewalls of the second nanostructured layers, etching the polymer layer formed on sidewalls of the second nanostructured layers, and forming source/drain structures in contact with the sidewalls of the second nanostructured layers and the polymer layer.

In some embodiments, a method includes forming a fin structure on a substrate, such that the fin structure includes alternating first and second nanostructured layers and etching edge portions of the first nanostructured layers in the fin structure to form cavities. The method further includes forming a polymer layer on sidewall surfaces of the second nanostructured layers and within the cavities, curing the polymer layer to crosslink the polymer layer, etching the polymer layer deposited on sidewall surfaces of the second nanostructured layers, and forming S/D epitaxial structures on the substrate to abut the fin structure and the polymer layer so that an air gap is formed between sidewall portions of the S/D epitaxial structures and the polymer layer.

In some embodiments, a structure includes a substrate, source/drain (S/D) structures on the substrate, nanostructured layers between adjacent S/D structures, where the nanostructured layers are separated from one another by a gate structure, and polymer-based spacer structures interposed between the gate structures and S/D structures, where each of the polymer-based spacer structures comprises an air gap.

The foregoing disclosure outlines features of several embodiments so that those skilled in the art may better understand the aspects of the present disclosure. Those skilled in the art will appreciate that they may readily use the present disclosure as a basis for designing or modifying other processes and structures for carrying out the same purposes and/or achieving the same advantages of the embodiments introduced herein. Those skilled in the art will also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a fin structure with a plurality of alternating first and second nanostructured layers;
etching side portions of each of the first nanostructured layers to form a recess at an end of each first nanostructured layer;
exposing the recess to a vapor comprising an organosilicon compound;
depositing a polymer layer in the recess and on sidewalls of the second nanostructured layers;
etching the polymer layer formed on sidewalls of the second nanostructured layers; and
forming source/drain structures in contact with the sidewalls of the second nanostructured layers and the polymer layer.

2. The method of claim 1, further comprising co-flowing ammonia with the organosilicon compound and trisilylamine (TSA), wherein the organosilicon compound is AMIa.

3. The method of claim 1, further comprising drawing the vapor within the recess using a capillary action.

4. The method of claim 1, further comprising forming the polymer using a mixture of gases comprising the organosilicon compound, trisilylamine (TSA), and trimethyl oxisilicate (TMOS).

5. The method of claim 1, further comprising forming the polymer using a mixture of gases comprising the organosilicon compound, trisilylamine (TSA), and methanol (MeOH).

6. The method of claim 4, further comprising performing a hydrogen-based treatment on the polymer layer for cross-linking the polymer layer.

7. The method of claim 6, further comprising performing the hydrogen-based treatment at about 500° C.

8. A method, comprising:
forming a fin structure on a substrate, wherein the fin structure comprises alternating first and second nanostructured layers;
etching edge portions of the first nanostructured layers in the fin structure to form cavities;
forming a polymer layer on sidewall surfaces of the second nanostructured layers and within the cavities;
curing the polymer layer to crosslink the polymer layer;
etching the polymer layer deposited on sidewall surfaces of the second nanostructured layers; and
forming S/D epitaxial structures on the substrate to abut the fin structure and the polymer layer so that an air gap is formed between sidewall portions of the S/D epitaxial structures and the polymer layer.

9. The method of claim 8, further comprising replacing the first nanostructured layers with a gate structure.

10. The method of claim 8, wherein forming the polymer layer comprises:
exposing the cavities and sidewall surfaces of the second nanostructured layers to a vapor comprising a polymer precursor and trisilylamine (TSA);
condensing the vapor within the cavities to form the polymer layer within the cavities at a first rate; and
condensing the vapor on sidewall surfaces of the second nanostructured layers at a second rate, wherein the second rate is less than the first rate.

11. The method of claim 10, further comprising condensing the vapor at about 5° C.

12. The method of claim 10, further comprising reacting the polymer precursor and TSA with trimethyl oxisilicate (TMOS).

13. The method of claim 10, further comprising reacting the polymer precursor and TSA with methanol (MeOH).

14. The method of claim 8, wherein curing comprises performing a hydrogen based treatment on the polymer layer.

15. The method of claim 8, wherein condensing the vapor within the cavities comprises forming a meniscus between the polymer layer and top and bottom inner sidewalls of the cavities.

16. A structure, comprising:
a substrate;
source/drain (S/D) structures on the substrate;
nanostructured layers between adjacent S/D structures, wherein the nanostructured layers are separated from one another by a gate structure;
polymer-based spacer structures interposed between the gate structures and S/D structures; and
an air gap disposed between the polymer-based spacer structures and the S/D structures.

17. The structure of claim 16, wherein the polymer-based spacer structures comprises carbon, oxygen, silicon, and nitrogen.

18. The structure of claim 16, wherein a portion of the gate structure is above the nanostructured layers and comprises a gate spacer on sidewall surfaces of the gate structure.

19. The structure of claim 16, wherein the polymer-based spacer structures are seamless.

20. The structure of claim 16, wherein the polymer-based spacer structures comprises a polymer layer with a dielectric constant less than about 4.
